(19) United States
(12) Patent Application Publication
(10) Pub. No.: US 2019/0079025 A1
(43) Pub. Date: Mar. 14, 2019

(54) Defect Inspection Device

(71) Applicant: Hitachi High-Technologies Corporation, Minato-ku, Tokyo (JP)

(72) Inventors: Masaki HASEGAWA, Tokyo (JP); Katsunori ONUKI, Tokyo (JP); Noriyuki KANEOKA, Tokyo (JP); Hisaya MURAKOSHI, Tokyo (JP); Tomohiko OGATA, Tokyo (JP)

(21) Appl. No.: 16/084,395

(22) PCT Filed: Mar. 16, 2016
(86) PCT No.: PCT/JP2016/058228

§ 371 Date: Sep. 12, 2018

(51) Int. Cl. G01N 21/95; G01N 23/203; H01J 37/29; G01N 21/88

(52) U.S. Cl. CPC G01N 21/9501; G01N 23/203; G01N 2021/8887; G01N 21/8851; H01J 2237/24475; H01J 37/29

(57) ABSTRACT

The purpose of the present invention is to provide a defect inspection device with which it is possible to detect a latent flaw with a high precision or at a high speed. In order to fulfill this purpose, this defect inspection device is provided with: a sample support member that supports a sample irradiated by an electron beam emitted from an electron source; a negative voltage applying power source for forming a retarding electric field in relation to the electron beam that irradiates the sample supported by the sample support member; an imaging element at which an image of electrons reflected without reaching the sample is formed via the retarding electric field; an ultraviolet light source that emits an ultraviolet light toward the sample; and a computation processing device that processes an image generated on the basis of a signal obtained by the imaging element. The computation processing device determines the type of defect in the sample on the basis of a plurality of image signals obtained when the ultraviolet light was emitted under at least two emitting conditions.

### TECHNICAL FIELD

The present invention relates to a wafer defect inspection method and a defect inspection device, especially relates to a method and a device for inspecting a defect on the basis of an image formed by charged particle emission.

### BACKGROUND ART

For wafer defect inspection, an electron beam device that evaluates an image formed by detecting an electron acquired by irradiating a sample with a charged particle beam is used. In Patent Literature 1, a defect inspection device that detects a flaw on the basis of an image signal acquired by electron beam emission is disclosed. In Patent Literature 1, the device that inverts an electron beam for irradiating the whole inspection field on a wafer surface in the vicinity of the wafer surface by applying negative voltage close to accelerating voltage of the emitted electron beam to a wafer, images the inverted electron on an electron lens and acquires an electron image for inspection is disclosed. An image can be formed by imaging the inverted electron (a mirror electron).

Besides, it is described in Non-patent Literature 1 that for application of such a mirror electron microscope, detecting a flaw of a semiconductor crystal can be given. In Non-patent Literature 1, it is described that a mirror electron image acquired in a state in which ultraviolet light irradiates is suitable for detecting a laminated defect of a SiC epitaxial layer. A charge generated inside a sample by the irradiation of ultraviolet light is captured by the laminated defect of the SiC epitaxial layer and an equipotential surface is distorted by local charge. As a shade is made in a mirror electron image even by slight distortion of the equipotential surface, the laminated defect can be detected at high sensitivity using the mirror electron microscope.

### CITATION LIST

### Patent Literature

Patent Literature 1: Japanese Patent No. 3534582 (Corresponding to U.S. Pat. No. 6,979,823)

### Non-Patent Literature

Non-patent Literature 1: M. Hasegawa and T. Ohno, J. Appl. Phys., 110,073507 (2001)

### SUMMARY OF INVENTION

### Technical Problem

In a semiconductor device manufacturing process, a minute circuit is formed on a semiconductor wafer polished to be a mirror finished surface. When a foreign matter and a flaw or a crystal defect, a converted layer of a crystal and others exist on such a wafer, a defect and material deterioration are caused in a circuit pattern formation process, a manufactured device is not normally operated, reliability of operation is deteriorated, and the manufactured device is not completed as a product.

The abovementioned SiC used for a power device is excellent in various properties including withstand voltage as power device material, compared with Si which is a heretofore used semiconductor, however, as SiC is excellent in chemical stability and is hard, fabricating to a wafer shape and polishing are difficult.

Before a device pattern is formed on a SiC wafer, a SiC epitaxial layer is formed. The wafer is finished to be a mirror finished surface by mechanical polishing, however, further, the surface flat at an atomic level and free from disturbance in a crystal is required to be made by applying chemo-mechanical polishing (CMP) to the wafer and removing a work-affected layer caused by the mechanical polishing. However, it is difficult to set optimum time for the CMP, the work-affected layer caused by the mechanical polishing remains inside the surface, and an extremely minute flaw may be formed. When a surface of a remaining work-affected region is flat and size of the flaw is small, it is difficult to detect them. Such an affected region and such a flaw will be called a latent flaw in the following description.

When an epitaxial layer is grown on a wafer surface on which a latent flaw remains, abnormality occurs with the latent flaw as a starting point in an atomic step and largely irregular structure may be formed. As high voltage resistance is remarkably deteriorated when a device is formed with the surface having such irregularities, the device cannot be used for a power device. Accordingly, inspection of whether a latent flaw remains or not is extremely important.

A defect can be revealed by observation in a locally charged state by ultraviolet light irradiation disclosed in Non-patent Literature 1 by the mirror electron microscope disclosed in Patent Literature 1, however, the defect has various types and the types may be unable to be sufficiently discriminated by the abovementioned mirror electron microscope. Especially, defects of different types may seem to be similar by ultraviolet light irradiation. In the meantime, ultraviolet light irradiation is a suitable method of revealing a defect, and compatibility of high-sensitivity detection of a defect and enhancement of defect discriminability are demanded. Besides, to enhance productivity of a wafer, acceleration of an inspection process is also demanded.

A defect inspection device having it as an object at least either to detect a latent flaw and others at high precision or to detect a latent defect and others at high speed will be proposed below.

### Solution to Problem

As one aspect for achieving the abovementioned object, the following defect inspection device is proposed. The defect inspection device is provided with a sample supporting member that supports a sample irradiated by an electron beam emitted from an electron gun, a negative voltage applying power source for generating a decelerating electric field for the electron beam that irradiates the sample supported by the sample supporting member, an imaging element in which an electron reflected without reaching the sample is imaged by the decelerating electric field, an ultraviolet light source that radiates ultraviolet light toward the sample and a processor that processes an image generated on the basis of a signal acquired by the imaging element. The processor determines a type of a defect of the sample on the basis of plural image signals acquired when the ultraviolet light is radiated on at least two radiation conditions.

### Advantageous Effects of Invention

According to the abovementioned configuration, the realization of high-precision defect determination or high-speed detection is enabled.

### BRIEF DESCRIPTION OF DRAWINGS

FIG. 1 illustrates an outline of a mirror electron microscope inspection device.

FIGS. 2A and 2B illustrate charge of a work-affected region (a latent flaw) caused by ultraviolet radiation.

FIGS. 3A and 3B illustrate a contrast formation principle of the mirror electron microscope.

FIG. 4 is a flowchart showing an inspection process using the mirror electron microscope.

FIG. 5 illustrates a display example of defect information acquired by the mirror electron microscope.

FIG. 6 illustrate variation of a mirror electron microscope image when an ultraviolet radiation condition is varied.

FIG. 7 illustrate variation of a mirror electron microscope image when an ultraviolet radiation condition is varied.

FIG. 8 illustrate variation of a mirror electron microscope image when an ultraviolet radiation condition is varied.

FIG. 9 is a flowchart showing an automatic defect inspection process using the mirror electron microscope.

FIG. 10 is a flowchart showing an automatic defect inspection process using the mirror electron microscope.

FIG. 11 is a flowchart showing a process for identifying a type of a defect on the basis of information acquired from a mirror electron microscope image.

FIG. 12 shows one example of a defect inspection system including the mirror electron microscope.

### DESCRIPTION OF EMBODIMENTS

For wafer inspection technique, technique (optical scatter type inspection technique) for detecting light scattered on a surface of a wafer by irradiating the wafer surface with light having wavelengths from visible light to ultraviolet light (hereinafter merely called light) and an inspection device applying optical microscope technique such as dark field imaging have been used. However, a defect cannot be detected by the abovementioned inspection technique using light because of development of micronization of a semiconductor device and others and quality control of wafers is hindered.

A work-affected region (a latent flaw) underneath the wafer surface having an important effect on epitaxial layer formation by SiC cannot be detected and controlled by the previous optical inspection technique. Therefore, as no means for evaluating whether a latent flaw exists underneath a wafer surface or not and surface density of latent flaws is provided even if improvement and acceleration of a CMP process are tried, optimum process conditions cannot be determined. As a result, technical development for enhancing productivity of wafers is hindered and a unit price of a SiC wafer cannot be reduced.

The following embodiments relate to a defect inspection device provided with a mirror electron microscope that can detect latent flaws and others, especially a mirror electron microscope that can realize high-speed and high-precision inspection. It has been considered that as density of impurities in a SiC wafer before epitaxial layer formation is higher by approximately ten thousand to hundred thousand times, compared with density of impurities in an epitaxial layer itself and conductivity is high, charge is not held even if charging a latent image by ultraviolet radiation is tried. However, as an existing area of a latent flaw is limited to the vicinity of a wafer surface, it is made manifest by research of these inventors that local charge is held for enough time required for observation even if density of impurities in the wafer is high.

In the following embodiments, a defect inspection device mainly provided with a mirror electron microscope that detects a mirror electron acquired by emitting an electron beam toward a location irradiated by ultraviolet light for acquiring plural mirror electron microscope images when ultraviolet light is radiated on first and second at least two conditions and identifying a defect using these plural mirror electron images will be described. More concretely, as for a portion in which contrast emerging in a mirror electron image varies, the mirror electron image and an image acquired by varying an ultraviolet radiation condition such as intensity of radiation are compared and a type of a defect is specified depending upon whether difference exists between the mirror electron images or not.

According to the abovementioned configuration, as a latent flaw and others inside a wafer surface before epitaxial layer growth can be specified, a state of the wafer surface after a CMP process can be appropriately evaluated. The CMP process can be optimized by such evaluation and enhancement of productivity of wafers is enabled.

### First Embodiment

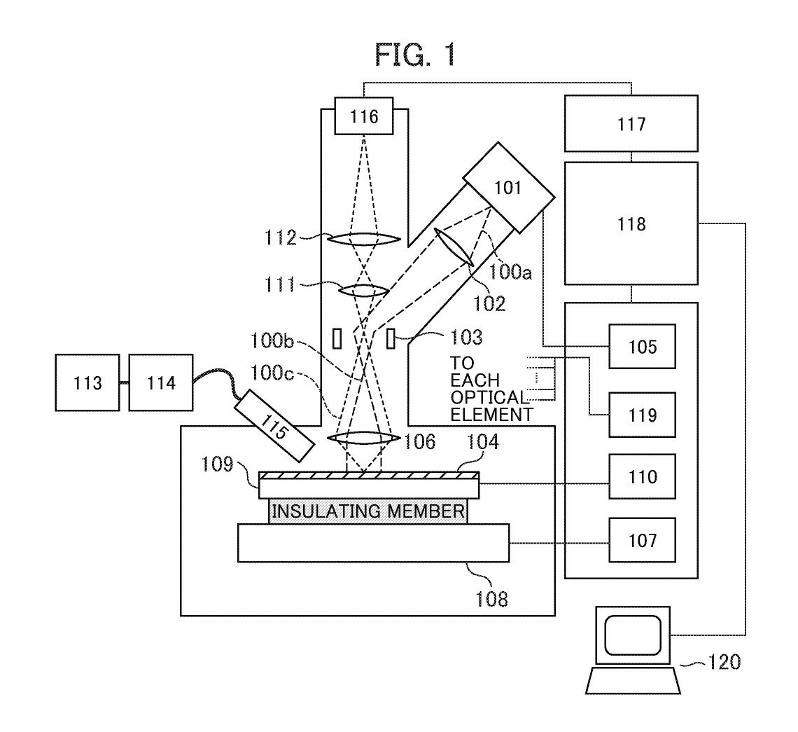

An inspection device using a mirror electron microscope will be described referring to FIG. 1 below. However, in FIG. 1, a pump for vacuum exhaust, its controller, an exhaust piping, a carriage system of detected wafers and others are omitted. Besides, an orbit of an electron beam is more exaggerated than an actual orbit for explanation.

First, emission of an electron beam will be described. An emitted electron beam 100a emitted from an electron gun 101 is deflected by a separator 103 to be an electron beam being an approximately parallel flux, being focused by a condenser lens 102 and the emitted electron beam irradiates a wafer 104 to be inspected. For the electron gun 101, a Zr/O/W type Schottky-emission electron source that has a small light source diameter and enables acquiring a large current value is used; however, an electron source such as a LaB6 electron source that enables acquiring a higher current value and a cold-cathode electron source higher in brightness may also be used. Besides, the electron gun 101 may also be a magnetic field superimposed immersion electron source gun in the vicinity of which an electromagnetic lens is arranged. Voltage and current required for operating the electron gun 101 such as extracting voltage of the electron gun 101, accelerating voltage of an emitted electron beam and heating current of an electron source filament are supplied and controlled by an electron gun controller 105. As an inside of the electron gun 101 is required to be maintained to be an ultra-high vacuum equal to or below 10⁻⁶ Pa when the Schottky-emission electron source and the cold-cathode electron source are used for an electron source, a vacuum valve for maintaining a vacuum in maintenance and others is provided.

In the figure, the condenser lens 102 is expressed as one lens, however, the condenser lens may also be an electro-optical system acquired by combining plural lenses and a multipole so as to acquire emitted electron beams higher in a degree of parallelization. The condenser lens 102 is adjusted so that electron beams are focused on a back focal plane of an objective lens 106. The objective lens 106 is an electrostatic lens or an electromagnetic lens respectively configured by plural electrodes.

The separator 103 is installed to separate an electron beam emitted toward the inspected wafer 104 and a mirror electron beam returned from the inspected wafer 104. In this embodiment, a separator utilizing an electron beam deflector is used. The electron beam deflector can be set to deflect an electron beam traveling from the upside and to make an electron beam traveling from the downside straightforward. In this case, an electron optical column for supplying an emitted electron beam is inclined as shown in FIG. 1 and an electron optical column for imaging a reflected electron is upright. Besides, for the separator, a deflector using only a magnetic field can also be used. A magnetic field is located in a perpendicular direction to an optical axis of an electron beam, the emitted electron beam is deflected in a direction of the inspected wafer 104, and an electron from the inspected wafer 104 is deflected in a direction reverse to the direction in which the emitted electron beam travels. In this case, an optical axis of the emitted electron beam column and an optical axis of the electron beam imaging column are laterally symmetrical with an optical axis of the objective lens in the center.

When aberration caused in deflecting the emitted electron beam 100a by the separator is required to be corrected, an arrangement for correcting aberration may also be additionally arranged. Besides, when the separator 103 is a magnetic deflector, an auxiliary coil is provided to correct aberration.

The emitted electron beam 100a deflected by the separator 103 is formed to be electron beams of a parallel flux vertically incident on a surface of the inspected wafer 104 by the objective lens 106. As described above, as the condenser lens for emission 102 is adjusted to focus electron beams on a back focal point 100b of the objective lens 106, electron beams high in a degree of parallelization can irradiate the inspected wafer 104. An area irradiated by the emitted electron beam 100a on the inspected wafer 104 has area of 10000 μm² for example. The objective lens 106 is provided with an anode for raising mirror electrons is provided on the upside of the surface of the inspected wafer 104.

A wafer holder 109 is installed on a moving stage 108 controlled by a moving stage controller 107 via an insulating member and the inspected wafer 104 is laid on the wafer holder. A method of driving the moving stage 108 is perpendicular two straight motions or a rotational motion having the center of the inspected wafer 104 in the rotational center and a straight motion in a radial direction of the wafer or a combination of these motions. Besides, in addition of these motions, a vertically straight motion and a motion in a gradient direction may also be added. The moving stage 108 locates the whole or a part of the surface of the inspected wafer 104 on an electron beam irradiation position, that is, on the electron optical axis of the objective lens 106 by these motions.

To turn the surface of the inspected wafer 104 negative potential, a high voltage power source 110 (a negative voltage applying power source) applies negative voltage approximately equal to accelerating voltage of the electron beam to the wafer holder 109. The emitted electron beam 100a is decelerated in front of the inspected wafer 104 by a decelerating electric field generated by the negative voltage applied to the wafer holder 109 (the sample supporting member). The negative voltage applied to the wafer holder 109 is minutely adjusted to invert an electron orbit in a reverse direction before the negative voltage collides with the inspected wafer 104. An electron reflected on the wafer becomes a mirror electron 100c.

The mirror electron 100c is focused by the objective lens 106 and other imaging lenses and is converted to an image signal by being projected on an imaging element. As the separator 103 is the electron beam deflector in this embodiment, the separator can be controlled so that no deflective action is applied to electron beams traveling from the downside, the mirror electron 100c directly travels in an upright imaging column direction, and a first image is sequentially imaged by an intermediate electron lens 111 and a projection electron lens 112.

The intermediate lens 111 and the projection lens 112 are an electrostatic or electromagnetic lens. A final electron image is extended and projected on an image detector 113. In FIG. 1, the projection electron lens 112 is expressed as one electron lens; however, the projection lens may also be configured by plural electron lenses and a multipole to extend with high magnification and to correct image distortion. Though they are not shown in FIG. 1, deflectors for more finely adjusting an electron beam, an astigmatic compensator and others are equipped if necessary.

Ultraviolet light from an ultraviolet light source 113 is dispersed by a spectroscope 114 and irradiates the inspected wafer 104 through an ultraviolet optical element 115. As the inspected wafer 104 is held in a vacuum, the ultraviolet light is divided into that on the air side and that on the vacuum side by a window made of material (for example, quartz) transmits the ultraviolet light and the ultraviolet light emitted from the ultraviolet optical element 115 irradiates the wafer through the window. Or the ultraviolet light source 113 may also be installed in the vacuum. In that case, a wavelength is not selected by the spectroscope 114 but a solid state component that emits ultraviolet light of a specific wavelength and others can also be used. An irradiation wavelength of the ultraviolet light shall be a wavelength corresponding to larger energy than a band gap of wafer materials for example. Or depending upon a situation of an energy level in the band gap of the wafer materials, a wavelength of energy smaller than band gap energy may also be selected for a wavelength that generates a carrier in semiconductor materials. Ultraviolet light is transmitted via an optical fiber and between the ultraviolet light source 113 and the spectroscope 114 and between the spectroscope and the ultraviolet optical element 115. Or the ultraviolet light source 113 and the spectroscope 114 may also be integrated. Besides, when a filter that transmits only wavelengths in a specific range can be provided to the ultraviolet light source 113, no spectroscope 114 may also be used.

The image detector 116 (the imaging element) converts an image of the mirror electron 100c to an electric signal and transmits the signal to a defect determination unit 117. The image detector 116 may also be configured by a fluorescent screen for converting an electric beam to visible light and a camera that images an electron image on the fluorescent screen for one example or may also be configured by a two-dimensional detector that detects an electron such as CCD for another example. A mechanism for doubling intensity of an electron image and intensity of fluorescence may also be provided.

A mirror electron image in each location on the surface of the wafer 104 is output from the image detector 116, driving the moving stage 108.

The moving stage 108 may also be stopped in each imaging or may also be continued to be moved at fixed speed without being stopped. In the latter case, the image detector 116 performs time delay integration (TDI) type imaging. As time for accelerating/decelerating the moving stage 108 is not required, high-speed inspection is enabled, however, moving speed of the moving stage 108 and a signal transfer rate (a line rate) of the imaging element are required to be synchronized.

An operating condition of each of various units including a condition of the abovementioned TDI imaging operation is input/output to/from an inspection system controller 118. Various conditions of accelerating voltage in generating an electron beam, electron beam deflection width, deflection speed, stage moving speed, image signal extraction timing from the image detector and an ultraviolet irradiation condition are input to the inspection system controller 118. The inspection system controller 118 comprehensively controls the moving stage controller 107, an electro-optical system controller 119 that controls each electro-optical element, a controller over the ultraviolet light source 113 and the spectroscope 114 and others. The inspection system controller 118 may also be configured by plural computers every role connected via a communication line. Besides, a monitor-equipped input-output unit 120 is installed and enables adjustment by a user of the detector, input of operating conditions, execution of inspection and others.

When an instruction for executing inspection is input from the user via the monitor-equipped input-output unit 120, the moving stage 108 is driven and a specified inspection starting point on the wafer 104 is moved immediately under the center of the objective lens 106. After the image detector 116 acquires a mirror electron image, the moving stage 108 is moved by quantity equivalent to a set value, the next mirror electron image is imaged, and the operation is repeated to an imaging position set as an inspection termination position. Until imaging of the substantially overall surface of the wafer 104 is finished, this operation may also be repeated, however, after fixed area of the wafer 104 is inspected, the moving stage is moved to another location, and inspection of fixed area may also be started again. It is the abovementioned TDI imaging of a mirror electron image that is more desirable when the substantially overall surface of the wafer 104 is inspected.

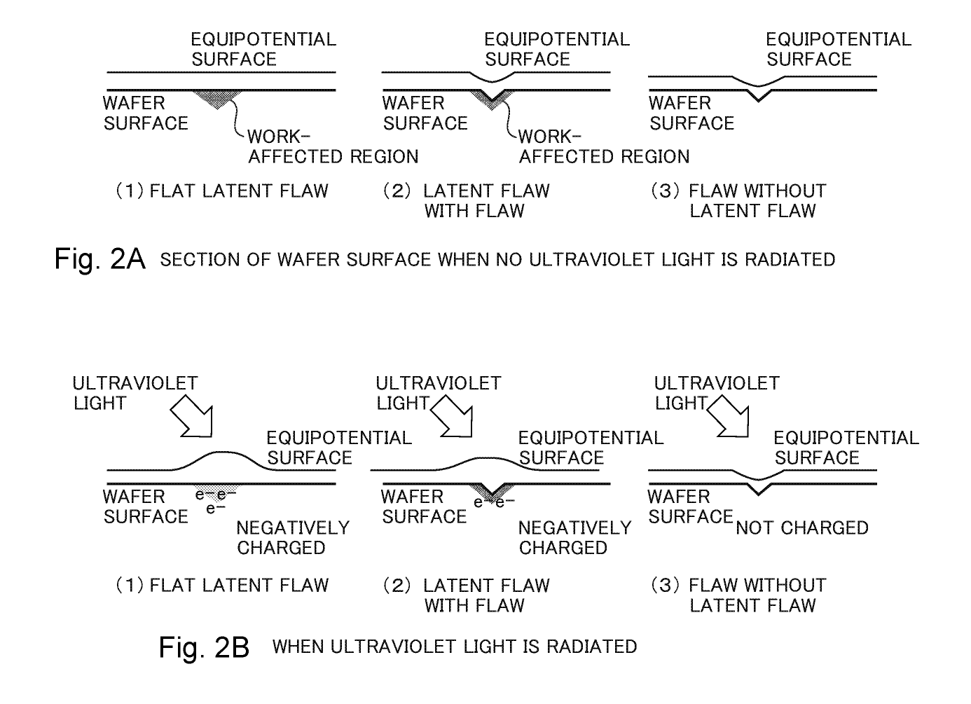

Next, a detection principle of a remaining work-affected region (a latent flaw) on the SiC wafer surface by the mirror electron microscope will be described referring to FIGS. 2A and 2B. In this embodiment, the remaining work-affected region is detected utilizing a charging phenomenon of the work-affected region by ultraviolet irradiation. FIG. 2A schematically shows a situation of a section of the wafer surface when no ultraviolet light irradiates. A drawing (1) shows a case that a work-affected region exists under the flat surface and shows the triangular work-affected region. As no irregularity exists on the surface in this case, no work-affected region is detected in a previous optical method. A drawing (2) shows a case that a concave such as a flaw exists on the surface and a work-affected region further remains inside the wafer. A drawing (3) shows a case that though a concave exists on the surface, no work-affected region exists inside the wafer. In the cases (2), (3), when each width of the concaves is wider than a diffraction limit, the work-affected region can be detected in the optical method, however, it cannot be discriminated whether the inside work-affected region exists or not. Equipotential surfaces on which an irradiating electron is inverted are also shown over the wafer surfaces together. As no local charging and no irregularity on the surface exist in the case (1), the equipotential surface is flat. As the concaves exist on the surfaces in the cases (2), (3) though no local charging exists, each equipotential surface is also concave along each contour.

FIG. 2B shows variation of potential when ultraviolet light irradiates these defective portions. For a wavelength of the irradiating ultraviolet light, a wavelength shorter than a wavelength corresponding to band gap energy (3.4 eV in a case of 4H-SiC normally used for a wafer) of wafer materials is appropriate. When the ultraviolet light irradiates, a carrier is generated inside to depth to which the ultraviolet light is transmitted. In a case of an n-type semiconductor, an electron is captured in a work-affected region and is locally negatively charged.

In a case of a p-type semiconductor, as a hole is captured, it is positively charged. Equipotential surfaces in drawings in FIG. 2B show cases that work-affected regions are negatively charged in the case of the n-type semiconductor. In a case in the drawing (1), a local negatively charged area is caused and the equipotential surface is boosted to be convex. In a case in the drawing (2), though the surface is concave, boost effect by negative charging is stronger and the equipotential surface is convex likewise. In a case in the drawing (3), as no charged area exists, the equipotential surface remains concave independent of whether ultraviolet light irradiates or not.

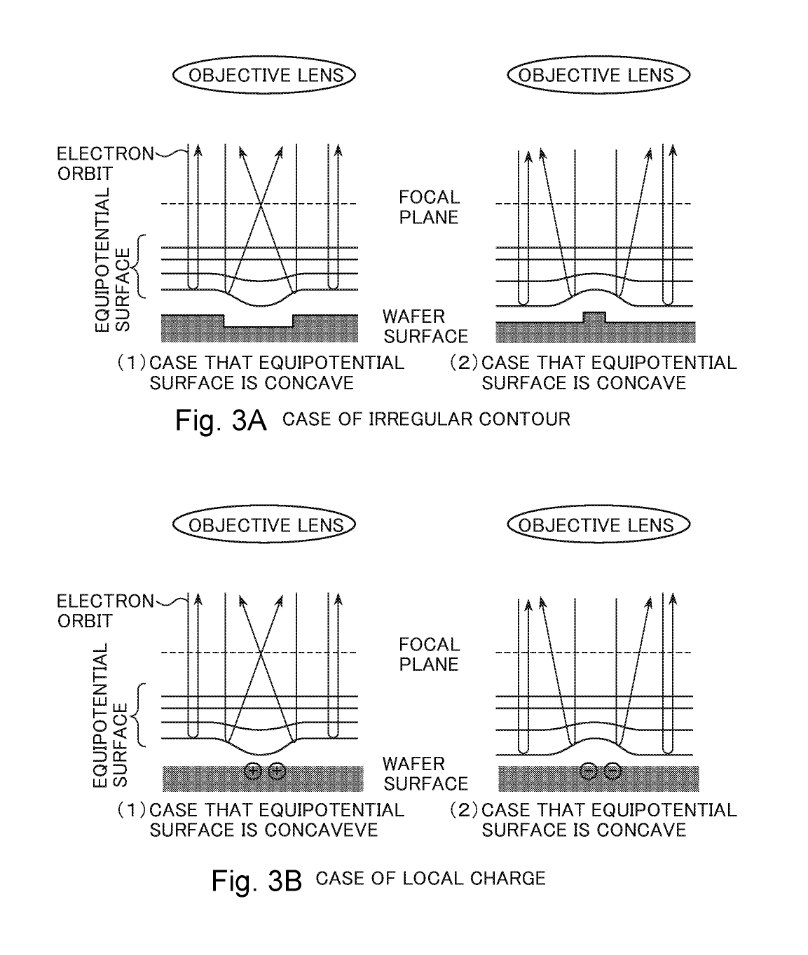

The mirror electron microscope converts irregularities on the equipotential surface to contrast and images it. Its principle will be generally described referring to FIG. 3A below. FIG. 3A schematically shows a situation of orbital inversion of an irradiating electron when irregularities exist on the surface. Equipotential surfaces are transformed according to superficial contours. In the mirror electron microscope, an irradiating electron beam irradiates the sample surface substantially parallelly and its orbit is inverted on a fixed equipotential surface. When the surface is concave and the equipotential surface is concave, the electron beam is inverted in a focused manner. In the meantime, when the surface is convex and the equipotential surface is boosted, an orbit of the electron beam is inverted in a dispersed manner.

The electron the orbit of which is inverted forms an electron image by the objective lens. Irregularities of the equipotential surfaces can be displayed as contrast of an electron image by displacing a focal plane of the objective lens from the sample surface. In FIGS. 3A and 3B, the focal planes are set on the upside of the surface as shown by a dotted line. In this case, when the equipotential surface is concave and orbits of electron beams are inverted, focusing the beams, the electron beams concentrate on the focal plane and emerge as a bright point in an electron image. In the meantime, when the equipotential surface is boosted and orbits of electron beams are inverted, dispersing the beams, density of electrons lowers on the focal plane and the electrons emerge as a dark portion in an electron image.

On such an optical condition that the focal plane is virtually set on the downside of the sample surface, contrary to the cases shown in FIGS. 3A and 3B, if the equipotential surface is convex, electrons emerge as a bright point and if the equipotential surface is concave, electrons emerge as dark contrast in an electron image. Besides, as shown in FIG. 3B, as an equipotential surface is concave or is boosted when an area locally positively or negatively charged exists even if the surface is even, electrons emerge as contrast in an electron image in the same way as irregularities on the surface. The example that a position of the focal plane is adjusted by the objective lens is described above, however, a focus of the objective lens is made fixed and a focal condition may also be adjusted by an intermediate electron lens and a projection electron lens respectively posterior.

When the phenomenon shown in FIGS. 2A and 2B and the mirror electron image formation principle shown in FIGS. 3A and 3B are utilized, discrimination of a defect such as a latent flaw by the mirror electron microscope is enabled. For example, in the case of the flat latent flaw shown in FIG. 2A, no contrast emerges in a mirror electron image in a state that no ultraviolet light is radiated, however, when ultraviolet light is radiated, the equipotential surface is boosted to be a situation shown in a drawing (2) in FIG. 3B, and dark contrast emerges in a mirror electron image. That is, when dark contrast is detected, radiating ultraviolet light, the dark contrast can be judged a latent flaw if the dark contrast disappears or is thinned by applying variation such as stopping radiation of ultraviolet light or decreasing intensity to an ultraviolet radiation condition.

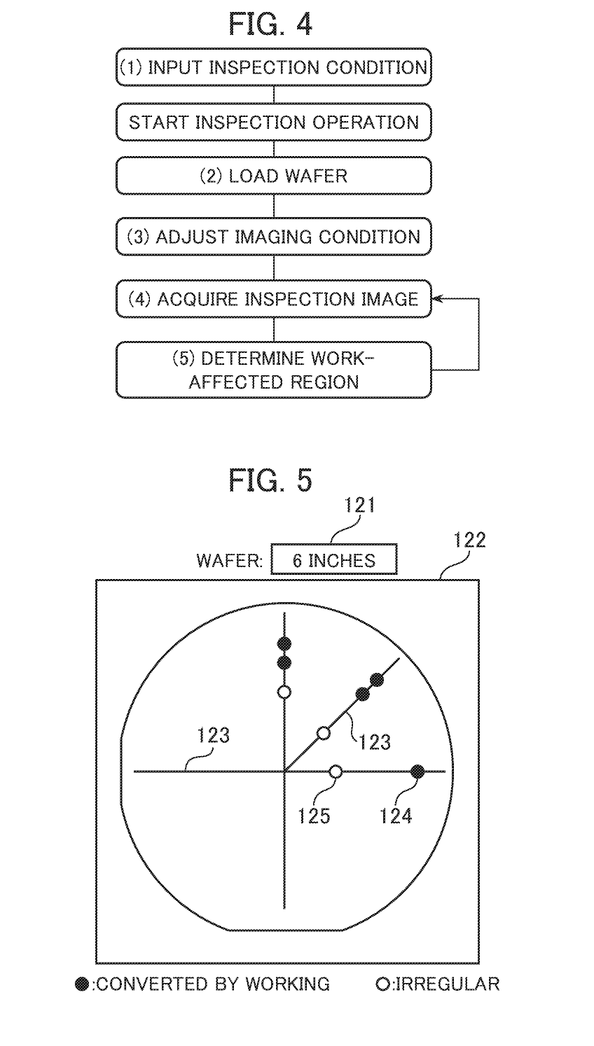

FIG. 4 shows a flow of inspection operation by the mirror electron microscope based upon the abovementioned principle. Each electro-optical element (the electron gun 101, the condenser lens 102, the separator 103, the objective lens 106, the intermediate electron lens 111, and the projection electron lens 112) of the inspection device, the image detector 116, an ultraviolet radiation system and others are set in a condition adjusted beforehand.

First, in a step for inputting an inspection condition (1), the user specifies an area to be inspected on a wafer. On the monitor-equipped input-output unit 120, an estimated number of imaged images, an estimated value of total inspection time and others are displayed in addition to a map of an inspected area and the monitor-equipped input-output unit is considered so that the user can set an efficient inspection condition. Various conditions as to an inspected area, order of inspection and others respectively set by the user are stored in the inspection system controller 118 and the same inspection operation can be applied to plural wafers when the user calls the conditions. When the user determines an inspection condition, the user instructs to start inspection operation via the monitor-equipped input-output unit 120. The inspection system controller 118 instructs to load a wafer onto the device when the controller receives an instruction.

In a step for loading the wafer (2), the wafer to be inspected 104 specified by the user is laid on the wafer holder 109 and the wafer holder 109 is installed on the moving stage 108 in the device. Afterward, the moving stage 108 is moved to a position specified beforehand by the user. In addition, negative potential stored in the inspection system controller 118 is applied to the wafer holder 109 by the high voltage power source 110. As for an anode for generating an electric field on the upside of the wafer 104 out of components of the objective lens 106, a risk of discharge can be reduced in application in this step depending upon a case.

In a step for adjusting an imaging condition (3), the wafer is moved to a wafer position specified by the user or registered in the inspection system controller 118 where the imaging condition is to be adjusted by the moving stage 108. In this position, an electron beam and ultraviolet light irradiate the wafer. Irradiation by the ultraviolet light may also be started by lighting the light source, a shutter is installed, and irradiation by the ultraviolet light may also be started by opening the shutter. Irradiation by an electron beam is executed by releasing blanking (not shown) or by opening a vacuum valve of the electron gun 101. A mirror electron image is fetched by the image detector 116 and is displayed on the monitor-equipped input-output unit 120. The user adjusts a negative voltage value supplied to the wafer holder 109 and other electro-optical condition, watching the displayed mirror electron image if necessary.

In a step for acquiring an inspection image (4), the moving stage is moved to an inspection starting position set by the user in the step (1) and the mirror electron image is acquired by the image detector 116, moving the moving stage according to imaging coordinates input in the step (1) under control from the moving stage controller 107. A condition of electro-optical elements required for acquiring the mirror electron image is maintained by the electro-optical system controller 119 at any time. The mirror electron image is analyzed by the defect determination unit 117 at any time and it is judged whether mirror electron image contrast of a specific contour is detected or not. This specific contour is registered in the defect determination unit 117 by the user beforehand and is a stripe, an ellipse and others for example. These are registered as a possible contour if a work-affected region remains.

In a step for determining a work-affected region (5), when the contrast of the mirror electron image estimated to be the work-affected region is detected in the step (4), the moving stage 108 is stopped and a type of the work-affected region is specified. This determination is executed by applying variation to intensity of radiated ultraviolet light and others according to the abovementioned basic principle. The type of the work-affected region is determined depending upon whether difference in the mirror electron image is found by the variation of the ultraviolet radiation condition or not. When the determination of the type of the defect is finished, the position of the moving stage, a determination result of whether the work-affected region exists or not and others are recorded in the inspection system controller 118 and the process is returned to the inspection image acquisition mode in the step (4) again.

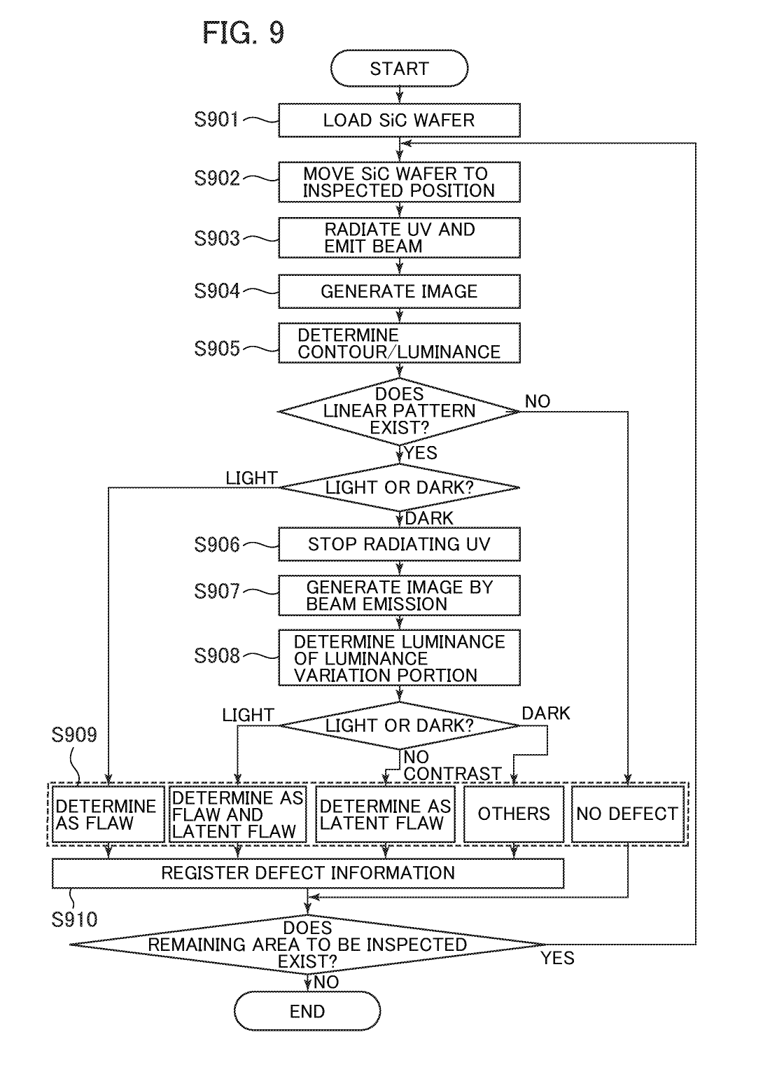

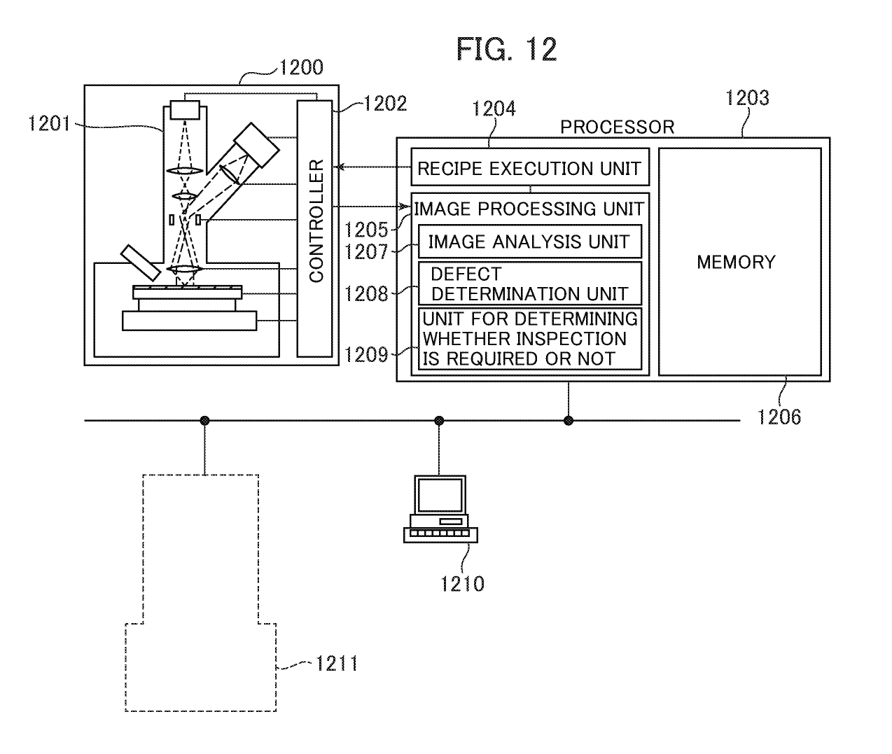

FIG. 9 is a flowchart showing a more concrete process for determining the type of the defect using the mirror electron microscope. Contents of the process shown in FIG. 9 are stored in a predetermined record medium as an operating program (a recipe) for controlling the electron microscope. FIG. 12 shows one example of a defect inspection system including a processor 1203 provided with a storage medium (a memory 1206) for storing the recipe for automatically executing defect inspection. The system shown in FIG. 12 includes the mirror electron microscope 1200 provided with a body 1201 of the mirror electron microscope and a controller 1202 that controls the mirror electron microscope, the processor 1203 that supplies a signal for controlling the mirror electron microscope 1200 and processes an image signal acquired by the mirror electron microscope, an input-output device 1210 for inputting required information and outputting inspection information and an external inspection device 1211.

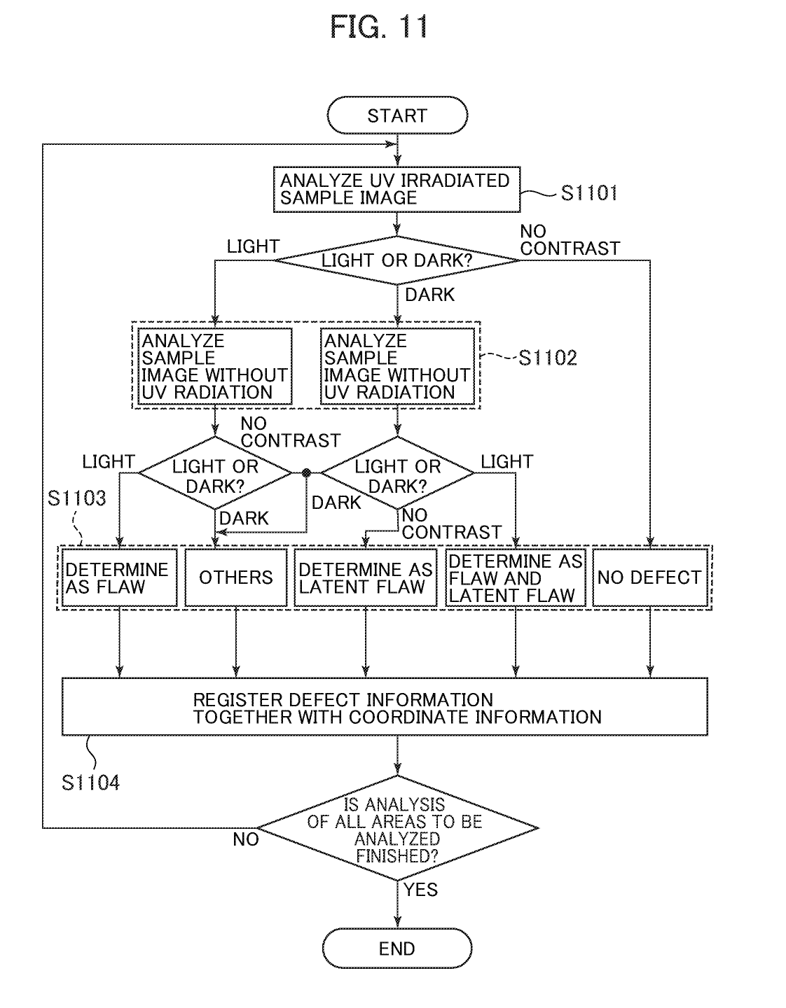

The processor 1203 includes a recipe execution device 1204 that transmits the operating program stored in the memory 1203 to the controller 1202 and an image processing device 1205 that processes an image signal acquired by the mirror electron microscope. The image processing device 1205 includes an image analysis unit 1207 that determines whether defect candidates and others are included in image data or not, a defect determination unit 1208 that determines a type of a defect out of defect candidates and a unit for determining whether inspection is required or not 1209 that determines whether or not re-inspection using the mirror electron microscope is to be executed on the basis of the determination of the defect. In the image analysis unit 1207, a dark portion and a bright portion are discriminated on the basis of binarization processing and others of an image for example and a contour and others of the dark area or the bright area are determined. In the determination of the contour, when a linear luminance variation area long in a specific direction and narrow in width for example exists, the portion is determined as a defect candidate. Besides, in the defect determination unit 1208, a type of the defect is specified according to flows shown in FIGS. 9 and 11. Further, a process by the unit for determining whether inspection is required or not 1209 for determining whether inspection based upon image acquisition is to be executed again or not on the basis of defect candidate information will be described in detail referring to the flowchart shown in FIG. 9 below.

The mirror electron microscope shown in FIGS. 1 and 12 executes automatic inspection according to the flowchart shown in FIG. 9. First, a sample (a SiC wafer in this embodiment) is loaded into a vacuum sample chamber in the mirror electron microscope (a step 901). Next, the moving stage 108 is controlled on the basis of inspection position information stored in the recipe so as to position an inspection object position in a position irradiated by an electron beam (a step 902). In a case of overall surface inspection, a position irradiated by an electron beam is positioned so that the whole area of the wafer is included. Next, an image in a state in which ultraviolet light irradiates is acquired by radiating ultraviolet light and emitting an electron beam respectively to the positioned inspection position (steps 903, 904). In the image analysis unit 1207, it is determined whether or not a predetermined contour area having contrast exists in an acquired image signal (a step 905). In this embodiment, as inspection that a linear pattern is determined as a defect is performed, a pattern except the linear pattern is not regarded as a defect, however, all images in which an area having contrast exists may also be determined as a defect candidate image without determining a contour. Besides, another contour may also be identified as a defect candidate.

Next, the unit for determining whether inspection is required or not 1209 generates an image on the basis of a determination result of contrast in the linear pattern by emitting an electron beam after stopping radiation of ultraviolet light (steps 906, 907) or determines a defect as a flaw without a latent flaw shown in the drawings (3) in FIGS. 2A and 2B (a step 909). The image analysis unit 1207 determines luminance in a linear portion in an image acquired in a state in which no ultraviolet light is radiated (a step 908). The defect determination unit 1208 determines a linear portion the evaluation of which varies from darkness to no contrast as a flat latent flaw utilizing the phenomenon shown in FIGS. 2A and 2B and determines a portion the evaluation of which varies from darkness to brightness as a latent flaw with a flaw (the step 909). When the linear portion remains dark independent of whether ultraviolet light is radiated or not, the linear portion may also be identified as an unknown defect and an error may also be caused under judgment that inspection is not suitably performed. Besides, the linear portion may also be evaluated as other crystal lattice distortion and may also be determined as no latent flaw. Moreover, when a type of such a defect can be specified, the linear portion may also be determined according to the type. The processor 1203 registers the abovementioned determination information (the defect identification information) and coordinate information of the wafer together in the memory 1206 and others (a step 910). The abovementioned processing is continued until inspection of the overall wafer or specified locations to be inspected is finished.

In this embodiment, for enhancing efficiency of inspection and accelerating inspection, as to a flaw without a latent flaw, an inspection process based upon image formation in which no ultraviolet light is radiated is skipped. Acquisition of an image in the state in which no ultraviolet light is radiated can be made minimum by adopting judgment algorithm described in this embodiment, enhancing efficiency of inspection and accelerating inspection can be realized. That is, effect of making a defective portion manifest by irradiation of ultraviolet light can be acquired, inhibiting labor in acquiring an image.

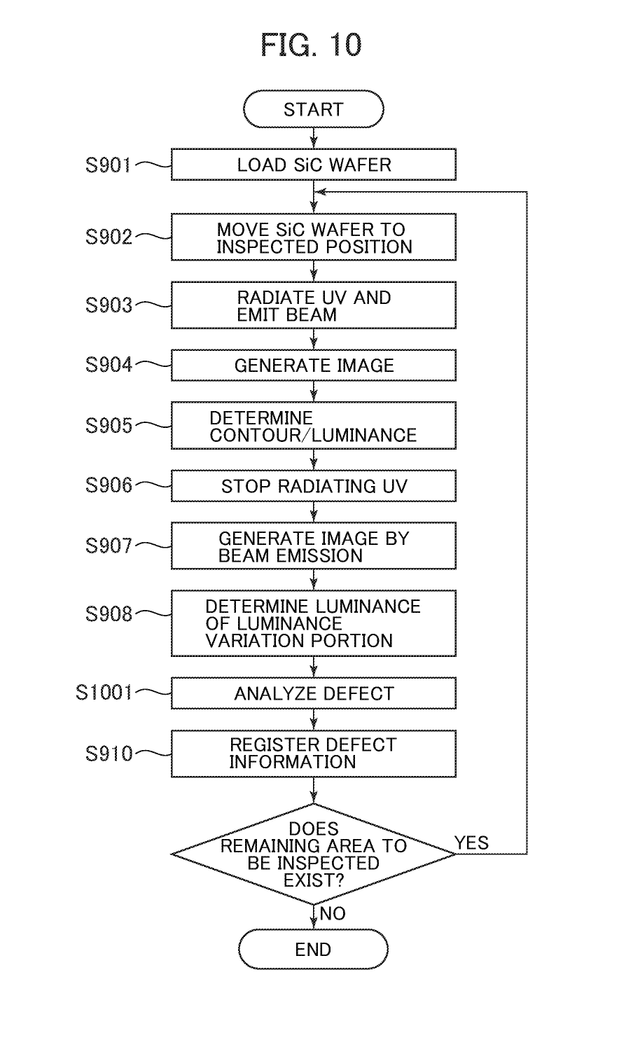

FIG. 10 is a flowchart showing a process for acquiring an image when ultraviolet light is radiated and an image when no ultraviolet light is radiated respectively as to the overall surface of the wafer or all specified inspection locations and determining a defect type. Steps 901 to 908 and 910 are the same steps as those in the flowchart shown in FIG. 9. In a step 1001, a defect type is determined on the basis of judgment algorithm shown in FIG. 11. In FIG. 10, an example that inspection by beam emission and defect analysis are both performed is shown, however, an image when ultraviolet light is radiated and an image when no ultraviolet light is radiated as to the overall surface of the wafer or all specified inspection locations are acquired and stored before and a defect may also be collectively determined later using the stored information.

In an analyzation process shown in FIG. 11, an image acquired when ultraviolet light is radiated is first analyzed and luminance of a contrast area discriminable from another portion is determined (a step 1101). When no contrast area is recognized, the image is identified as no defect (a step 1103). Next, an image acquired when no ultraviolet light is radiated is analyzed and luminance of a contrast area is determined (a step 1102). On the basis of this analysis result, a contrast area the evaluation of which varies from darkness to no contrast is determined as a flat latent flow, a contrast area the evaluation of which varies from darkness to brightness is determined as a latent flaw with a flaw, a contrast area the evaluation of which varies from brightness to brightness is determined as a flaw without a latent flaw, and other contrast areas are determined as other crystal lattice distortion, no latent flaw, an unknown defect or uninspectable (an error) (a step 1103).

As described above, high-precision detect of a defect can be realized by using not mere luminance information but information related to variation of an image when a charging condition is varied for a determination criterion of a defect.

An inspected position may also be specified on the basis of coordinate information of a defect acquired in an external inspection device 1211 such as an optical inspection device.

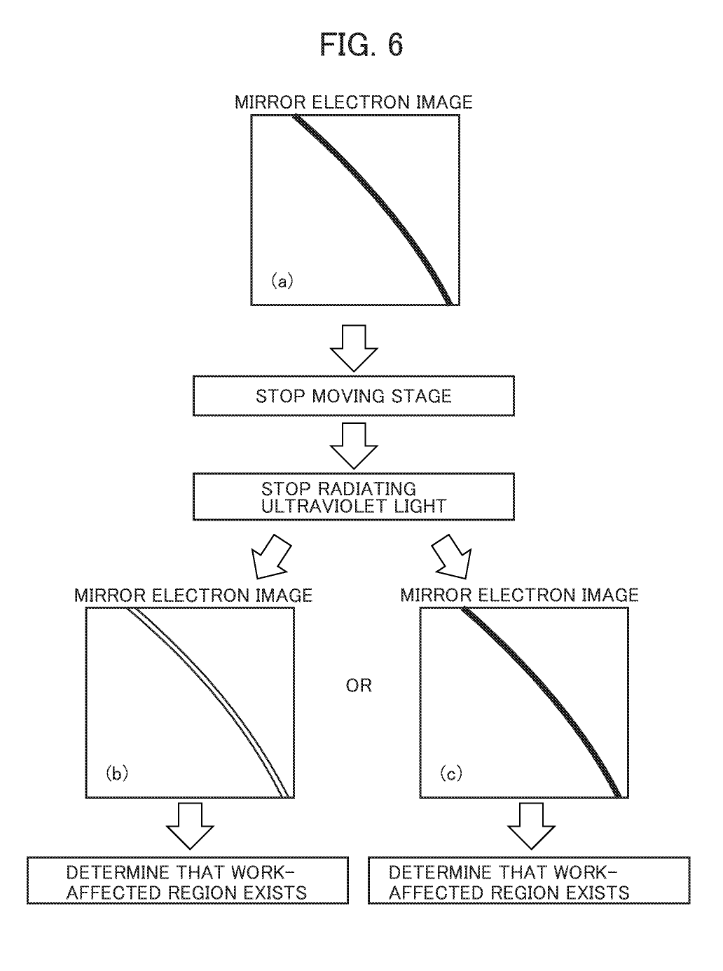

FIG. 6 show a process for determining a work-affected region of an n-type 4H-SiC wafer before epitaxial layer formation. FIG. 6(a) shows a model of linear contrast emerging in the mirror electron image in the step (4) in FIG. 4. The focal plane of the objective lens is set on the upside of the wafer surface and when the equipotential surface is transformed to be convex, dark contrast emerges. Dark linear contrast shown in FIG. 6(a) shows that a work-affected region may be locally negatively charged.

It is judged in image processing by the defect determination unit 117 and the image analysis unit 1207 for example whether dark contrast emerges in the mirror electron image or not. The inspection system controller 118 stops the moving stage 107 and proceeds to determination work of whether the contrast is formed by negatively charging the work-affected region or is a reflection of a convex contour on the plane. Variations shown as the models in FIG. 6 by variation of an ultraviolet radiation condition for the mirror electron image in the work-affected region are one example and the variations are various depending upon width and depth of the work-affected region. A variation as a judgment criterion of mirror electron image contrast is set by the user in consideration of size of a work-affected region to be detected.

Ultraviolet irradiation of the wafer can be stopped by closing the shutter of the ultraviolet light source 113. when the dark contrast varies to bright contrast as shown in the model of the mirror electron image shown in FIG. 6(b) in stopping ultraviolet radiation, it is determined that the dark contrast is a linear work-affected region with a concave on the surface corresponding to the case (2) in FIGS. 2A and 2B. In the meantime, when variation is hardly found as shown in FIG. 6(c), it is determined that no work-affected region exists. The variation of the mirror electron image before and after stopping ultraviolet radiation is judged by making a differential image between the mirror electron image shown in FIG. 6(a) and the mirror electron image shown in FIG. 6(b) or FIG. 6(c) in the defect determination unit 117 and depending upon whether the difference exceeds likelihood of preset difference or not.

When imaging of mirror electron images in an inspection range set by the user is finished, the inspection system controller 118 instructs the monitor-equipped input-output unit 120 to display a position of the moving stage in which the work-affected region is imaged in a map. FIG. 5 shows a display example on a graphical user interface (GUI) of the monitor-equipped input-output unit 120. Only a map of work-affected regions is extracted. On this GUI, size of a wafer to be inspected is displayed in a wafer size display field 121. An inspection result is displayed together with an outline of the wafer in a map display area 122. A position continuously imaged on the wafer is displayed as observation location display 123. A location determined as a work-affected region in determining the work-affected region in the step (5) is displayed as work-affected region existence location display 124. A location determined that no work-affected region exists is also displayed as display 125 in a state in which the location is discriminated from a work-affected region. Besides, further classification is made depending upon difference in mirror electron image contrast and an extent of difference by the variation of the ultraviolet radiation condition if necessary and a result may also be displayed in the map display area 112. Moreover, a location in which the equipotential surface is convex while ultraviolet light irradiates may also be selectively displayed in the abovementioned map as a possible location of a work-affected region.

According to this embodiment, the work-affected region (the latent flaw) of the SiC wafer can be detected in the inspection device using the mirror electron microscope.

### Second Embodiment

In the first embodiment, the example that ultraviolet radiation and ultraviolet non-radiation can be switched by opening/closing the shutter of the ultraviolet light source has been described. In this embodiment, variation of a mirror electron image caused by varying intensity of ultraviolet radiation is captured and it is determined whether a work-affected region exists or not.

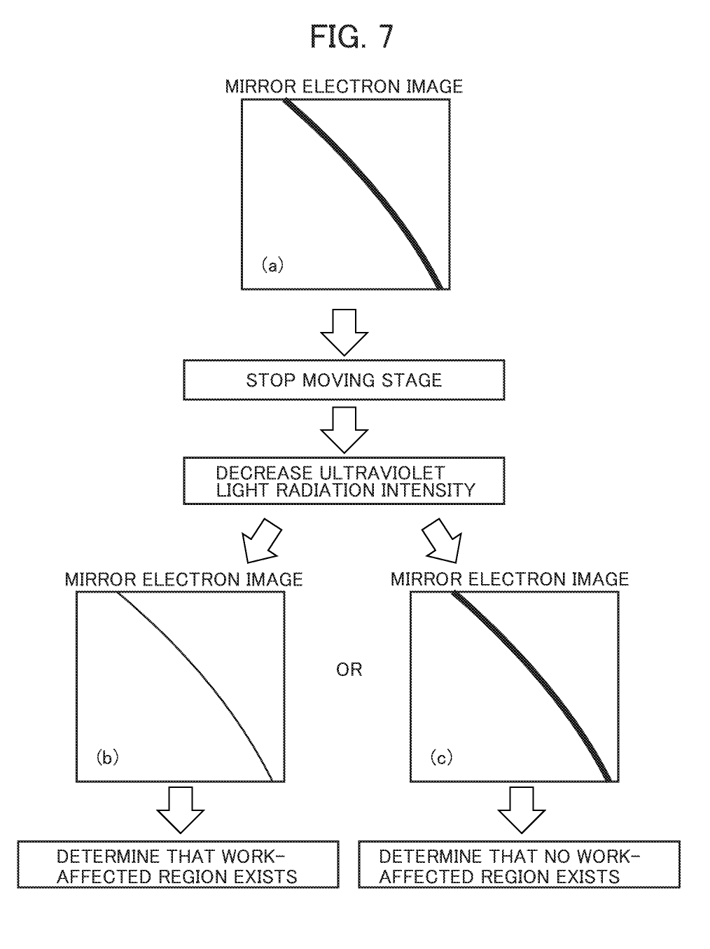

FIG. 7 illustrate a method of determining a work-affected region by decreasing ultraviolet intensity. As in FIG. 6, the determination method with an n-type 4H-SiC wafer before epitaxial layer formation as an object is shown. FIG. 7(a) shows a model of linear contrast emerging in a mirror electron image while a wafer surface is inspected in the step (4) shown in FIG. 4. The model shows that a work-affected region may be locally negatively charged. In this embodiment, setting of ultraviolet intensity of an ultraviolet light source 113 is varied and intensity of ultraviolet radiation toward the wafer is decreased. When the ultraviolet light source 113 itself has no ultraviolet intensity setting function, a beam attenuator using a filter and a diaphragm is added.

When width and darkness of a stripe as in a model of a mirror electron image shown in FIG. 7(b) vary in decreasing ultraviolet radiation intensity, it is determined that the linear contrast is a linear work-affected region with a concave on the wafer surface corresponding to the case (2) in FIGS. 2A and 2B. In the meantime, when variation is hardly found as in FIG. 7(c), it is determined that no work-affected region exists. The variation of the mirror electron image before and after stopping ultraviolet light is judged by making a differential image between the mirror electron image shown in FIG. 7(a) and the mirror electron image shown in FIG. 7 (b) or 7C in the defect determination unit 117 and depending upon whether the difference exceeds likelihood of preset difference or not.

The variations caused by the variation of the ultraviolet radiation condition for the mirror electron image in the work-affected region shown as the models in FIG. 7 are one example and the variations are various depending upon width and depth of the work-affected region. A variation of mirror electron image contrast as a judgment criterion is set by the user in consideration of size of a work-affected region to be detected.

According to this embodiment, in the inspection device using the mirror electron microscope, the work-affected region (the latent flaw) of the SiC wafer can be detected.

### Third Embodiment

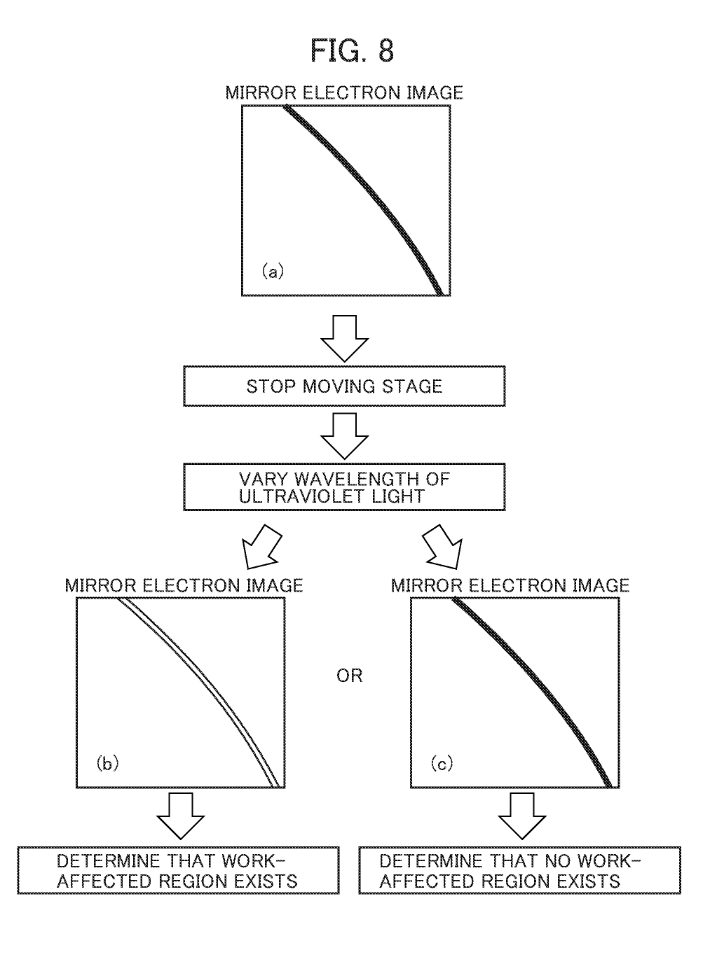

In the abovementioned embodiments, the inspection devices that determine whether the work-affected region exists or not utilizing the variation of ultraviolet radiation intensity have been described. In this embodiment, a method of determining based upon displacement of an image acquired by varying a wavelength of radiated ultraviolet light will be described. FIG. 8 illustrate a method of determining a work-affected region by varying an ultraviolet wavelength. As shown in FIG. 6, the method of determining an n-type 4H-SiC wafer before epitaxial layer formation is shown. FIG. 8(a) shows a model of linear contrast emerging in the mirror electron image while the wafer surface is inspected in the step (4) in FIG. 4. FIG. 8(a) shows that a work-affected region may be caused by being locally negatively charged.

In this embodiment, a wavelength of radiated ultraviolet light is varied by controlling a spectroscope 114 and others. The wavelength of radiated ultraviolet light is varied from the wavelength corresponding to higher energy than a band gap of 4H-SiC to a wavelength corresponding to lower energy than the band gap. Ultraviolet light or visible radiation light of the wavelength corresponding to lower energy than the band gap cannot generate a carrier in the wafer and cannot supply charge to a work-affected region. When dark contrast varies to bright contrast as shown in a model of a mirror electron image shown in FIG. 8 (b) in varying a wavelength of radiated ultraviolet light, it is determined that a linear work-affected region with a concave on a surface corresponding to the case (2) shown in FIGS. 2A and 2B exists. In the meantime, when the dark contrast hardly varies as shown in FIG. 8(c), it is determined that no work-affected region exists. Variation of the mirror electron image before and after stopping ultraviolet light is judged by making a differential image between the mirror electron image shown in FIG. 8(a) and the mirror electron image shown in FIG. 8 (b) or 8C in a defect determination unit 117 and depending upon whether the difference exceeds likelihood of preset difference or not.

The variations shown as the models in FIG. 8 caused by variation of an ultraviolet radiation condition for the mirror electron image in the work-affected region are one example and the variations are various depending upon width and depth of the work-affected region. A variation of mirror electron image contrast as a judgment criterion is set by a user in consideration of size of a work-affected region to be detected.

In this embodiment, a wavelength of radiated ultraviolet light is varied under control of a spectroscope 114, however, the wavelength of radiated ultraviolet light may also be varied by being provided with plural filters having different wavelengths and mechanically replacing these. At that time, a filter replacement function is controlled by an inspection system controller 118 so that the filters can be replaced automatically or by a user via a monitor-equipped input-output unit 120.

According to this embodiment, in the inspection device using the mirror electron microscope, the work-affected region (the latent flaw) of the SiC wafer can be detected.

### Fourth Embodiment

In the abovementioned embodiments, when the equipotential surface is convex and contrast of the mirror electron image similar to a preregistered contour is detected, the moving stage 107 is stopped, the radiation condition of the ultraviolet light source 113 is varied, and it is determined whether a work-affected region exists or not. In this embodiment, an inspection area set on a wafer is first inspected on a first ultraviolet radiation condition and all mirror electron images are recorded in an inspection system controller 118 or in a storage or a medium annexed to the inspection system controller. Next, the inspection area set again is inspected on a second ultraviolet radiation condition (including stopping ultraviolet radiation) and all mirror electron images are stored. Afterward, the images according to the first ultraviolet radiation condition and the images according to the second ultraviolet radiation condition are compared in the same location as each imaged position. For example, a differential image is made, a location in which difference equal to or exceeding allowed image intensity difference is found is determined as a work-affected region, and the work-affected region is displayed in a map. These processing may also be executed by the inspection system controller 118 and an image analysis unit may also be separately equipped to execute these processing.

### LIST OF REFERENCE SIGNS

100a - - - Emitted electron beam, 100b - - - Posterior focus, 100c- - - Mirror electron, 101 - - - Electron gun, 102 - - - Condenser lens, 103 - - - Separator, 104 - - - Inspected wafer, 105 - - - Electron gun controller, 106 - - - Objective lens, 107 - - - Moving stage controller, 108 - - - Moving stage, 109 - - - Wafer holder, 110 - - - High voltage power source, 111 - - - Intermediate electron lens, 112 - - - Projection electron lens, 113 - - - Ultraviolet light source, 114 - - - Spectroscope, 115 - - - Ultraviolet optical element, 116 - - - Image detector, 117 - - - Defect determination unit, 118 - - - Inspection system controller, 119 - - - Electro-optical system controller, 120 - - - Monitor-equipped input-output unit, 121 - - - Wafer size display field, 122 - - - Map display area, 123 - - - Observation location display, 124 - - - Work-affected region existence location display, 125 - - - Display

1. A defect inspection device, comprising:
a sample supporting member that supports a sample irradiated by an electron beam emitted from an electron source;
a negative voltage applying power source for generating a decelerating electric field for the electron beam which irradiates the sample supported by the sample supporting member;
an imaging element by which an electron reflected without reaching the sample is imaged by the decelerating electric field;
an ultraviolet light source that radiates ultraviolet light toward the sample; and
a processor that processes an image generated on the basis of a signal acquired by the imaging element,
wherein the processor determines a type of a defect of the sample on the basis of a plurality of image signals acquired when the ultraviolet light is radiated on at least two radiation conditions.

2. The defect inspection device according to claim 1,
wherein the processor determines a type of the defect on the basis of an image signal acquired when the ultraviolet light is radiated and an image signal acquired when no ultraviolet light is radiated.

3. The defect inspection device according to claim 1,
wherein the processor determines that a defect exists on the sample in a case that predetermined variation exists between a plurality of images acquired when the ultraviolet light is radiated on the at least two radiation conditions.

4. The defect inspection device according to claim 3,
wherein a state in which the ultraviolet light is radiated and a state in which no ultraviolet light is radiated are included in the at least two radiation conditions.

5. The defect inspection device according to claim 3,
wherein radiation conditions different in ultraviolet intensity are included in the at least two radiation conditions.

6. The defect inspection device according to claim 3,
wherein radiation condition different in a wavelength are included in the at least two radiation conditions.

7. The defect inspection device according to claim 1, comprising a moving stage for moving the sample,
wherein the processor stops the moving stage on the basis of an image signal acquired when the electron beam is emitted in a state in which the ultraviolet light is radiated; and
the processor determines whether or not an image signal based upon emission of the electron beam is to be acquired in a state in which the ultraviolet radiation condition is varied.

8. The defect inspection device according to claim 1,
wherein the processor determines a type of the defect on the basis of combination of characteristics extracted from the plurality of image signals.

9. The defect inspection device according to claim 1,
wherein the processor determines a type of the defect according to variation between the plurality of images.

10. A defect inspection device, comprising:
a sample supporting member that supports a sample irradiated by an electron beam emitted from an electron source;
a negative voltage applying power source for generating a decelerating electric field for the electron beam that irradiates the sample supported by the sample supporting member;
an imaging element in which an electron reflected without reaching the sample is imaged by the decelerating electric field;
an ultraviolet light source that radiates ultraviolet light toward the sample; and
a processor that processes an image generated on the basis of a signal acquired by the imaging element,
wherein the processor determines whether a second image is to be acquired on the basis of a first image acquired when the ultraviolet light is radiated on a first radiation condition by varying an ultraviolet radiation condition or transition to the next inspection area is to be made.
